(19) United States
(12) Patent Application Publication
(10) Pub. No.: US 2019/0067081 A1
(43) Pub. Date: Feb. 28, 2019

(54) WAFER EDGE PROTECTION FOR CRACK-FREE MATERIAL GROWTH

(71) Applicant: Intel Corporation, Santa Clara, CA (US)

(72) Inventors: Sanaz K. GARDNER, Hillsboro, OR (US); Sansaptak DASGUPTA, Hillsboro, OR (US); Marko RADOSAVLJEVIC, Beaverton, OR (US); Han Wui THEN, Portland, OR (US); Seung Hoon SUNG, Porland, OR (US)

(21) Appl. No.: 16/083,859

(22) PCT Filed: Mar. 30, 2016
(86) PCT No.: PCT/US2016/025021

§ 371 Date: Sep. 10, 2018

(51) Int. Cl. H01L 21/768; H01L 23/31; H01L 23/00; H01L 29/20; H01L 33/20; H01L 33/44

(52) U.S. Cl. CPC H01L 21/768; H01L 23/3185; H01L 33/44; H01L 29/2003; H01L 33/20; H01L 23/562

(57) ABSTRACT

A method of fabricating a wafer is disclosed. The method includes forming a protective layer on a device side and a non-device side of a substrate of the wafer. The method further includes removing the protective layer from a center portion of the device side of the substrate while retaining the protective layer in an edge portion of the substrate. The method also includes forming semiconductor layer in the center portion of the device side of the substrate while the protective layer is in the edge portion of the substrate.

### BACKGROUND

Many semiconductor devices in development leverage non-silicon semiconductor materials, including compound semiconductor materials such as III-Nitride (III-N) materials, Gallium arsenide (GaAs), Indium phosphide (InP), Indium gallium arsenide (InGaAs), Indium arsenide (InAs), among others. For example, III-N materials, as well as other materials with wurtzite crystallinity, such as, but not limited to Silver iodide (AgI), Zinc oxide (ZnO), Cadmium sulfide (CdS), Cadmium selenide (CdSe), a-Silicon carbide (a-SiC), and Boron nitride (BN), show particular promise for high voltage and high frequency applications like power management ICs and RF power amplifiers. In another example, III-N heteroepitaxial (heterostructure) field effect transistors (HFET), such as high electron mobility transistors (HEMT) and metal oxide semiconductor (MOS) HEMT, employ a semiconductor heterostructure with one or more heterojunctions. A heterojunction may be at an interface of, for example, a Gallium nitride (GaN) semiconductor and another III-N semiconductor alloy, such as Aluminium gallium nitride (AlGaN), Aluminum indium nitride (AlInN), or Indium gallium nitride (InGaN). GaN-based HFET devices benefit from a relatively wide bandgap (˜3.4 eV), enabling higher breakdown voltages than silicon-based metal-oxide-semiconductor field-effect transistors (MOSFETs), as well as high carrier mobility. III-N materials are also useful for photonics (e.g., light-emitting diodes (LEDs)), photovoltaics, and sensors, one or more of which may be useful to integrate into an electronic device platform.

### BRIEF DESCRIPTION OF THE DRAWINGS

The present disclosure described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIGS. 1A and 1B illustrate a wafer fabrication process using edge protection, according to an implementation.

FIG. 2 is a cross-sectional view depicting a device from a wafer fabricated using edge protection, according to an implementation.

FIG. 3 illustrates a top-level view of a wafer fabricated using edge protection, according to an implementation.

FIG. 4 illustrates an edge portion of a substrate, according to an implementation.

FIG. 5 illustrates a Raman profile of a wafer fabricated using edge protection and without using edge protection, according to an implementation.

FIG. 6 is a flow diagram of a wafer fabrication process, according to an implementation.

FIG. 7 illustrates an interposer, according to implementations.

FIG. 8 is a computing device built in accordance implementation of the present disclosure.

### DETAILED DESCRIPTION

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Demand for integrated circuits (ICs) with greater levels of semiconductor device integration is increasing. Many semiconductor devices use non-silicon materials, such as III-N materials and in particular Gallium nitride (GaN). Non-silicon materials grown on substrates, such as silicon (Si) substrates, may experience epitaxial issues such as lattice mismatch and mismatch of the coefficient of thermal expansion (CTE) (also referred to a thermal mismatch) between materials. For example, in the fabrication of high-voltage (HV) transistors multiple layers of III-N material, such as GaN, may be grown on a silicon wafer. The thermal mismatch between GaN and Si may be greater than 115%. Additionally, GaN epitaxy may be performed at high growth temperatures (e.g., greater than 1000° C.). After growth of a GaN layer on a Si wafer, the GaN layer cools and contracts faster than the underlying Si wafer that may cause deformation and cracks in the wafer. While buffer engineering may be used in the center of the wafer to balance out the thermal strain from thermal mismatch, the areas around the edge of the wafer may not be protected, which may lead to cracks in the wafer.

The present disclosure addresses the above-mentioned and other deficiencies by using edge protection in the fabrication of a wafer. Edge protection may include forming a protective layer on a device side and a non-device side of the substrate of a wafer. The protective layer, such as silicon nitride, silicon dioxide, or a combination thereof, is removed from a center portion of the device side of the substrate while the protective layer is retained in an edge portion of the substrate. A semiconductor layer, such as GaN, may be grown on the center portion of the device side of the substrate and on at least part of the protective layer in the edge portion of the substrate. The protective layer in the edge portion of the substrate may serve as edge protection to alleviate the thermal strain in the edge portion of the wafer and prevent cracking in the wafer.

In one implementation, one or more protective layers of silicon nitride, silicon dioxide, or a combination thereof, coat a device side and non-device side of a Si substrate. The protective layers on the device side of the substrate are coated with a resist. The resist is removed from the center portion of the substrate, while the resist is retained in the edge portion. The edge portion may include the bevel of the substrate and may include some portion of the substrate a distance of X millimeters from the bevel of the substrate. The protective layer on the device side is etched to the Si substrate, and the resist in the edge portion may be used to mask the protective layers in the edge portion. The resist in the edge portion is removed leaving the protective layers in the edge portion on the device side of the substrate. A semiconductor material, such as GaN, is grown in the center portion of the substrate and on at least part of the protective layer in the edge portion of the substrate. The semiconductor layer in the center portion may be crystalline while the semiconductor layer on the protective layer in the edge portion may be non-crystalline (which may include at least amorphous material and/or poly-crystalline material). The non-crystalline material in the edge portion is removed and the crystalline semiconductor layer in the center portion may be retained.

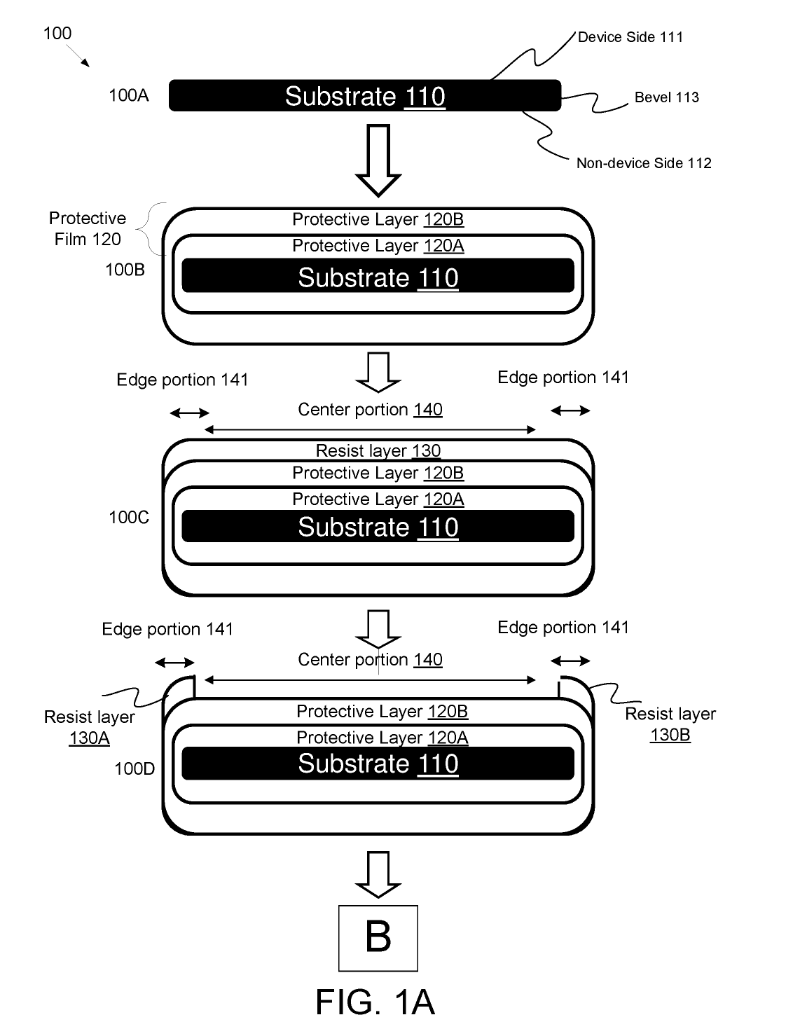

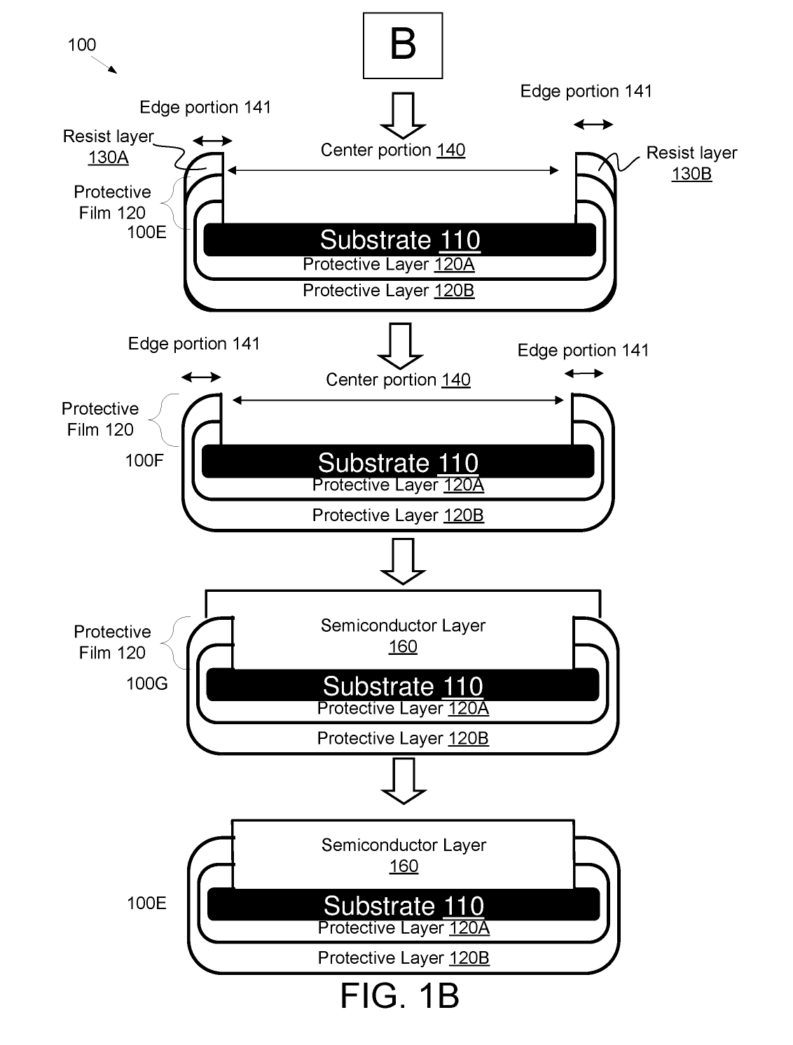

FIGS. 1A and 1B illustrate a wafer fabrication process using edge protection, according to an implementation. Fabrication process includes wafer 100 at various stages of the fabrication process, according to one exemplary implementation. It should be appreciated that fabrication process of FIGS. 1A and 1B is shown for purposes of illustration, rather than limitation. Fabrication process may be performed in any order, include any number of processes, and include more, the same, or fewer processes.

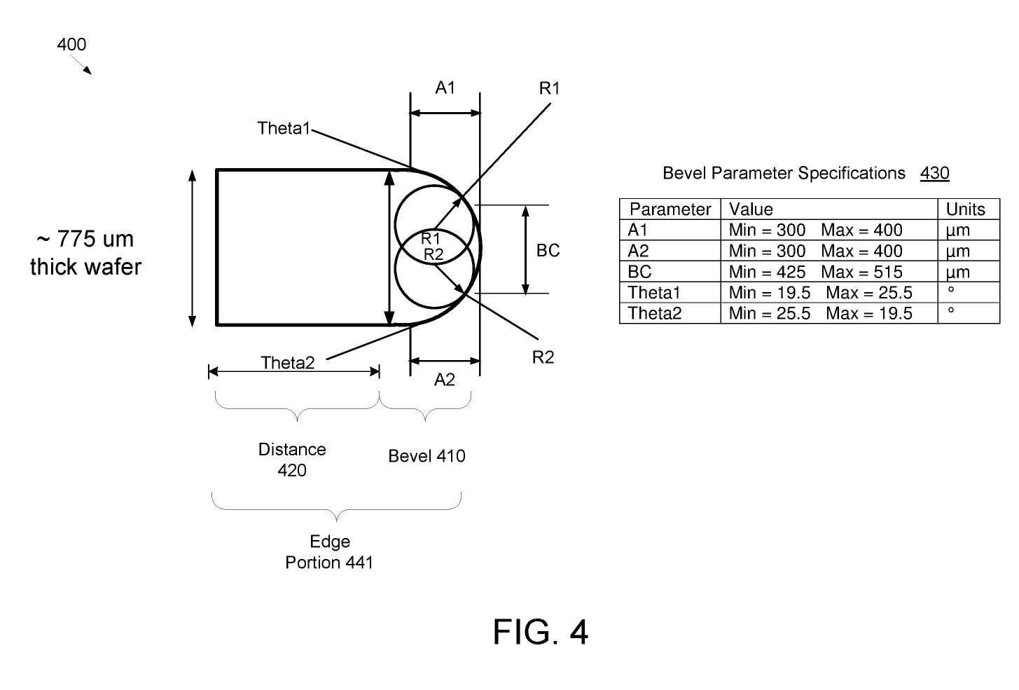

Wafer 100A illustrates a substrate 110 with a device side 111, non-device side 112, and bevel 113. Although not illustrated, device side 111, non-device side 112, and bevel 113 as illustrated by wafer 100A applies to subsequent wafers 100B through 100E. Details of bevel 113 are further described at least with respect to FIG. 4. Substrate 110 may be a variety of materials, including, but not limited to, silicon, germanium, Silicon germanium (SiGe), Gallium arsenide (GaAs), Indium phosphide (InP), and/or 3C-Silicon carbide (3C-SiC). Substrate 110 may be silicon on insulator (SOI). In one exemplary implementation, substrate 110 is silicon. Crystallographic orientation of a substantially monocrystalline substrate 110 may be any of (100), (111), or (110). Other crystallographic orientations are also possible. The crystallographic orientations of substrate 110 may be offcut. In one implementation, substrate 110 is (100) silicon with crystalline substrate surface region having cubic crystallinity. In another implementation, for a (100) silicon substrate 110, the semiconductor surface may be miscut, or offcut, for example 2-10° toward [110]. In another implementation, substrate 110 is (111) silicon with crystalline substrate surface region having hexagonal crystallinity.

At wafer 100B, substrate 110 may be coated with one or more protective layers, such as protective layer 120A and/or protective layer 120B, to form a protective film 120. Film may refer to multiple layers of a material. Two protective layers are shown for purposes of illustration, rather than limitation. One or more protective layers may be used. Protective film 120 may cover the device side 111 and the non-device side 112 (and bevel 113) of substrate 110. In one implementation, protective film 120 is formed using a vertical furnace. It should be appreciated that protective film 120 may be formed using other techniques. Protective film 120 may be a variety of materials, including but not limited to, an amorphous material. In one implementation, the amorphous material may be compatible with a process technique, such as GaN epitaxy and/or Front End (FE) processing. Protective film 120 may also include one or more of dielectrics and/or refractory metals, such as Aluminum oxide (Al2O3) on top of Tungsten (W) or Titanium nitride (TiN) or Molybdenum. In one implementation, protective film 120 may be silicon nitride, silicon oxide, silicon dioxide (SiO₂), or a combination thereof. For example, protective layer 120A may be silicon nitride of approximately 5-20 nanometers (nm) thickness and protective layer 120B may be silicon dioxide of approximately 10-30 (nm) thickness.

At wafer 100C, a resist layer 130 is formed above protective film 120 on the device side 111 of substrate 110. Resist layer 130 may be a variety of materials, including but not limited to carbon. In one implementation, resist layer may be a carbon based hard mask applied by a spin-on process. The thickness of the resist layer 130 may be controlled by the spin speed during the spin-on process. The thickness of resist layer 130 in the edge portion 141 of substrate 110 may be controlled to be thicker than the resist layer 130 in the center portion 140 of substrate 110. Edge beads of resist layer 130 may be formed in the edge portion 141 of substrate 110. At wafer 100D, resist layer 130 is removed from the center portion 140, while resist layer 130A and resist layer 130B of resist layer 130 are retained at the edge portion 141 of substrate 110.

Fabrication process of FIG. 1A may continue in FIG. 1B at wafer 100E, where protective film 120 is removed from center portion 140 of device side 111 of substrate 110 while protective film 120 is retained in edge portion 141 of substrate 110. Resist layer 130A and resist layer 130B in the edge portion 141 of substrate work to mask the protective film 120 underneath the resist layer 130A and 130B in edge portion 141. At wafer 100F, resist layer 130A and resist layer 130B are removed to form edge protection with protective film 120 in the edge portion 141.

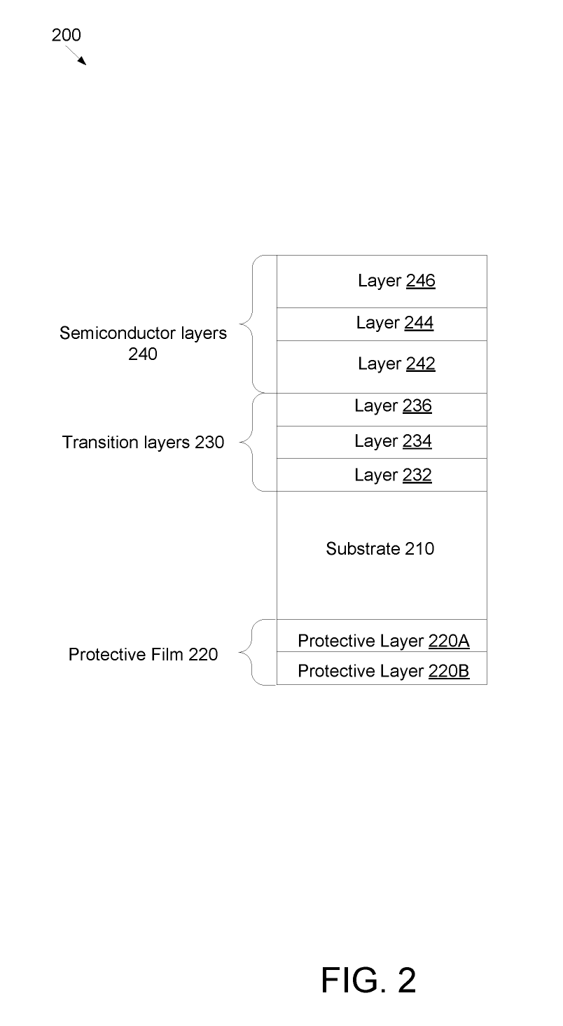

In one implementation (not illustrated), one or more transition layers (also referred to as buffer layers or buffer engineering) are formed in the center portion 140 of substrate 110 prior to the formation of semiconductor layer 160. The transition layers may be formed between substrate 110 and semiconductor layer 160 to help counter stress from thermal mismatch between substrate 110 and semiconductor layer 160. Transition layers may further be described at least with respect to FIG. 2.

At wafer 100G, semiconductor layer 160 is formed in center portion 140 of the device side 111 of substrate 110 while protective film 120 is in edge portion 141 of substrate 110. Semiconductor layer 160 may be an III-N material, grown by metal organic chemical vapor deposition (MOCVD) or molecular beam epitaxy (MBE) using nitrogen gas (N2) or ammonia (NH3), for example. In one implementation, semiconductor layer 160 is grown in center portion 140 and on at least part of protective film 120 in edge portion 141. Although not illustrated, center portion 140 and edge portion 141 correspond to the same areas illustrated in the preceding description of wafer 100C-100F. The part of semiconductor layer 160 on center portion 140 is crystalline while the part of semiconductor layer on the protective film 120 on edge portion 141 are non-crystalline. Non-crystalline may refer amorphous material and/or poly-crystalline material. The non-crystalline properties of semiconductor layer 160 in edge portion 141 help facilitate the removal of the non-crystalline part of semiconductor layer 160. Although a single semiconductor layer 160 is illustrated, one or more semiconductor layers may be formed on substrate 110. Although semiconductor layer 160 is shown a blanket layer, it should be appreciated that semiconductor layer 160 may be grown in pattern areas on wafer 100.

Semiconductor layer 160 may be a non-silicon material such as an III-N material. In some implementations, semiconductor layer 160 may be a III-N material, such as, but not limited to Aluminium gallium nitride (AlGaN), Aluminum indium nitride (AlInN)(e.g., 82% Al and 18% In), Indium gallium nitride (InGaN), Aluminum nitride (AlN), Gallium Nitride (GaN)(e.g., GaN, p-type GaN, n-type GaN), Indium aluminum gallium nitride (InAlGaN), and oxides of the aforementioned such as Gallium oxide (Ga2O3). It should be appreciated that semiconductor layer 160 may be one or more of a family of wurtzite semiconductors including at least AgI, ZnO, CdS, CdSe, a-SiC, and BN, and may include other non-silicon material systems, such as, but not limited to GaAs, InP, InAs, InGaAs, Indium gallium phosphide (InGaP), diamond, etc.

At wafer 100E, semiconductor layer 160 may be etched to remove the non-crystalline part of semiconductor layer 160 in edge portion 141 while retaining the crystalline part of semiconductor layer 160 in center portion 140. In one implementation, a hydroxide containing material, such as Tetramethylammonium hydroxide (TMAH), may be used to remove the non-crystalline part of semiconductor layer 160 selective to the crystalline part of semiconductor layer 160.

Thermal mismatch between substrate 110 and semiconductor layer 160 may be greater than 75%, and/or within a range of 75% to 200%. Thermal mismatch may be refer to the following equation: (CTE of material one−CTE material two)/CTE of material two×100=percentage thermal mismatch. For example, the CTE of GaN (e.g., material one) is 5.59×10⁻⁶ (per Kelvin) and the CTE of Si (e.g., material two) is 2.6×10⁻⁶ (per Kelvin). The thermal mismatch of GaN and Si is approximately 115%.

FIG. 2 is a cross-sectional view depicting a device from a wafer fabricated using edge protection, according to an implementation. In one implementation, device 200 may be an integrated circuit die from wafer 100 with respect to FIGS. 1A and 1B. Protective film 220 includes protective layer 220A and protective layer 220B, and may be correspond to protective film 120, protective layer 120A, and protective layer 120B respectively of FIGS. 1A and 1B. Substrate 210 may correspond to substrate 110 of FIGS. 1A and 1B.

Transition layers 230 include layer 232, layer 234, and layer 236. Although transition layers 230 include three layers, transition layers 230 may include one or more layers. In one implementation, transition layers may be part of a buffer engineering process to help manage the stress caused by thermal mismatch between substrate 210 and semiconductor layers 240. It should be appreciated that in some implementations, for example the fabrication of radio frequency (RF) filters, transition layers 230 may not be used.

Transition layers 230 may be one or more of a number of non-silicon materials. For example, transition layers 230 may be a hexagonal interfacial material including one or more of AlN, GaN, AlGaN (e.g., with different Al compositions), Titanium aluminium nitride (TiAlN), Hafnium Nitride (HfN), BN, SiC, Scandium nitride (ScN), or ZnO. In another example, transition layers 230 may be a cubic interfacial material including one or more of Aluminum arsenide (AlAs), AlAs on GaAs, Gallium phosphide (GaP), or Magnesium oxide (MgO).

In one implementation, transition layers 230 include layer 232 (e.g., base layer). Each of the transition layers 230 may have any of the exemplary compositions described herein in regards to transition layers 230. Layer 232 may have a thickness of 10 nm-500 nm. In some implementations, layer 232 is a nucleation layer, such as AlN.

In some implementations, additional layers of transition layers 230, such as layer 234 and 236 (e.g., intervening layers), may perfect a compositional grading between the compositions of the layer 232 (e.g., base layer) and layer 242 of semiconductor layers 240. In one exemplary implementation where layer 232 (e.g., base layer) is AlN and layer 242 of semiconductor layers 240 is GaN, the layers 234 and 236 decrement Al with a complementary increment in Ga. Thicknesses of each intervening layer may be selected to appropriately compensate thermal stress. For example, stress on a silicon substrate induced by the formation of a GaN crystalline structure may be counteracted, at least in part, by the formation of transition layers 230. In some implementations, each intervening layer, such as layer 234 and layer 236, may be between 100 nm and 300 nm.

Semiconductor layers 240, such as layer 242, may be correspond to semiconductor layer 160 of FIGS. 1A and 1B. Semiconductor layers 240 include layer 242, layer 244, and 246. It should be appreciated that semiconductor layer 240 may include one or more semiconductor layers.

In one implementation, semiconductor layers 240 may include two layers, such as layer 242 and layer 246 (not layer 244). Layer 242 may be GaN and layer 246 may be AlGaN or AlN or AlInN. Semiconductor layers 240 may form a GaN channel of a GaN transistor.

In another implementation, semiconductor layers 240 may include three layers, such as layer 242, layer 244, and layer 246. Layer 242 may n-type GaN (e.g., Si doped), layer 244 may be GaN and/or InGaN multi-quantum wells (MQWs), and layer 246 may be p-type GaN (e.g., Magnesium (Mg) doped). Semiconductor layers 240 may form an active area of a light emitting diode (LED).

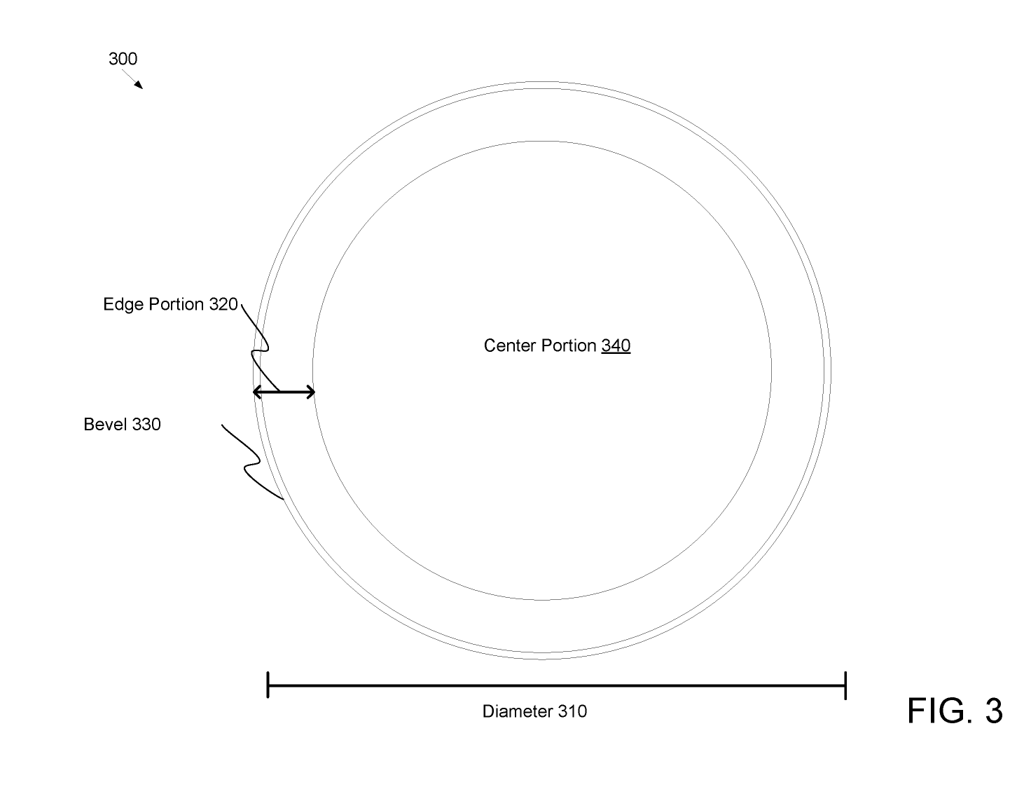

FIG. 3 illustrates a top-level view of a wafer fabricated using edge protection, according to an implementation. Wafer 300 includes diameter 310. Diameter of wafer 310 may be 200 mm or 300 mm or larger. Wafer 300 includes bevel 330, edge portion 320, and center portion 340. Edge portion may include bevel 330 and may include a distance from bevel 330 towards the center of wafer 300. The distance (X) from the bevel 300 may be 0 mm to 45 mm.

FIG. 4 illustrates an edge portion of a substrate, according to an implementation. Wafer 400 illustrated edge portion 441. Edge portion 441 may include bevel 410 and a part of the substrate some distance 420 from bevel 410. Distance 420 may range from 0 mm to 45 mm. Bevel parameter specifications 430 show dimensions of bevel 410, according to one example. It should be appreciated that bevel 410 may have other dimensions.

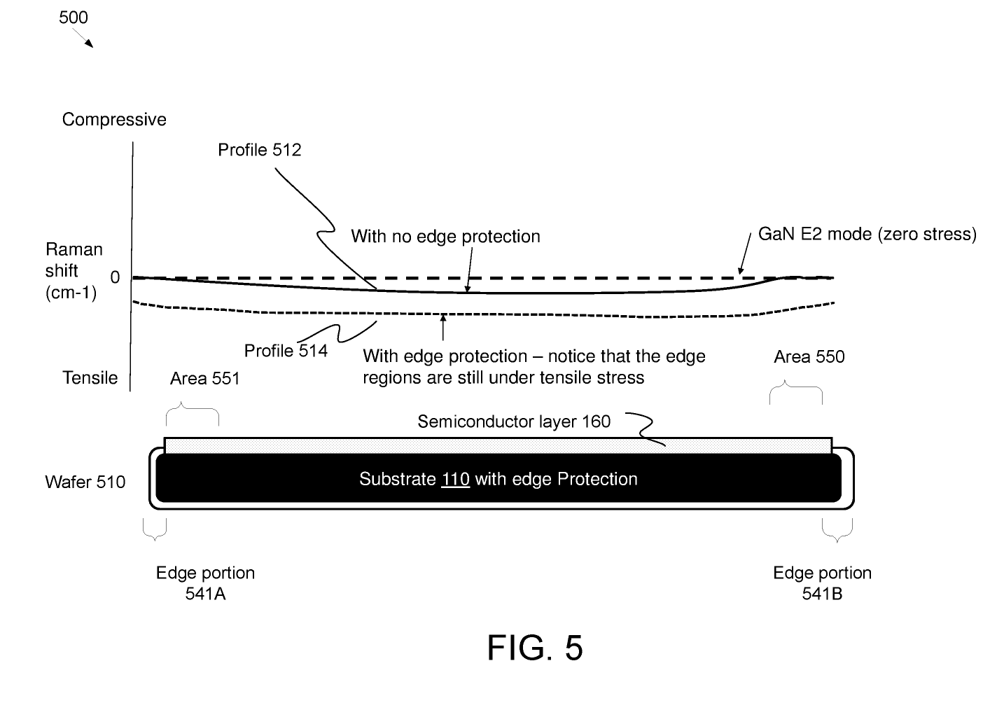

FIG. 5 illustrates a Raman profile of a wafer fabricated using edge protection and without using edge protection, according to an implementation. Raman profile graph 500 illustrates a graph where the center axis is at zero Raman shift (centimeters ⁻¹(cm⁻¹)) representing a condition of zero stress. A positive Raman shift (above zero Raman shift) along the positive direction of the y-axis represents an increasing compressive strain, and a negative Raman shift (below zero Raman shift) along the negative direction of the y-axis represents an increasing tensile strain. Profile 514 represents the Raman profile of wafer 510 having been fabricated using edge protection, as described at least with respect to FIGS. 1A and 1B. Profile 512 represents the Raman profile of a wafer (not shown) having been fabricated using no edge protection. Points along profile 514 correspond to points of wafer 510 directly underlying profile 514. For example, the left end of profile 514 corresponds to edge portion 541A of wafer 510 and the right end of profile 514 corresponds to edge portion 541B of wafer 510. Although a wafer without edge protection is not illustrated, points along profile 512 may correspond to points of a wafer (not shown) similarly positioned to wafer 510.

Wafer 510 may include a substrate 110 and at least one semiconductor layer, such as semiconductor layer 160. Substrate 110 may be a silicon substrate and semiconductor layer 160 may be GaN. Edge portion 541A and 541B may be similar to edge portion as described with at least respect to FIGS. 1A, 1B, and 3. Profile 514 (with edge protection) compared with profile 512 (without edge protection) illustrates that wafer 510 has greater tensile strain throughout the wafer, than a comparable wafer fabricated without edge protection. In one implementation, the wafer 510 at area 550 and area 551 a distance from edge portion 541A and 541B have a tensile strain in the range of 0 centimeters ⁻¹(cm⁻¹) to −1.4 (cm⁻¹). The distance may have a range of 0-30 mm. A similar wafer fabricated without edge protection may have compressive strain in the corresponding areas. Integrated circuit dies cut from the area 550 and area 551 may have similar tensile strain profiles as described above with respect to area 550 and area 551.

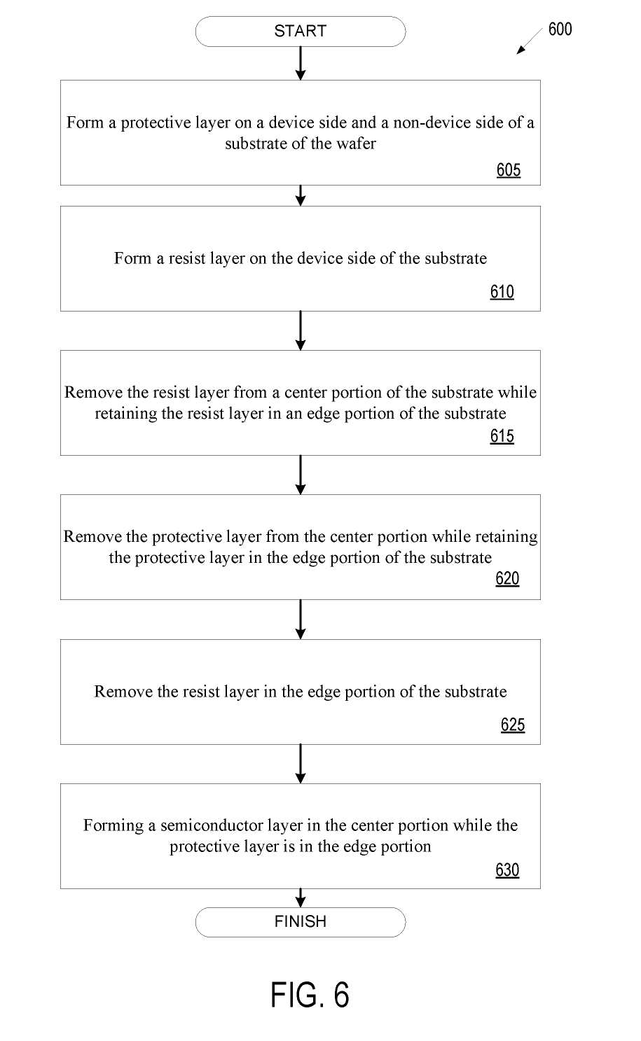

FIG. 6 is a flow diagram of a wafer fabrication process, according to an implementation. It should be appreciated that features of FIGS. 1A-5 may be described below to help illustrate method 600. Method 600 may be performed as operations. It should be appreciated that method 600 may be performed in any order and may include the same, more, or fewer operations. It should be appreciated that method 600 may be performed by one or more pieces of semiconductor fabrication equipment or fabrication tools.

Method 600 begins at operation 605 that forms a protective layer (e.g., protective layer 120A) on a device side 111 and a non-device side 112 of a substrate 110 of the wafer 100. At operation 610, resist layer 130 is formed on device side 111 of substrate 110. At operation 615, resist layer 130 is removed from the center portion 140 of substrate 110 while resist layer 130A and 130B is retained in the edge portion 141 of substrate 110. At operation 620, protective layer 120A is removed from the center portion 140 of substrate 110 while the protective layer 120A is retained in the edge portion 141 of the substrate 110. Resist layer 130A and 130B help to mask protective layer 120A in the edge portion 141. At operation 625, the resist layer 130A and 130B is removed in the edge portion 141 of the substrate 110. At operation 630, semiconductor layer 160 is formed in the center portion 140 while the protective layer 120A is in the edge portion 141. Additional details of method 600 may be described at least with respect to FIGS. 1A and 1B.

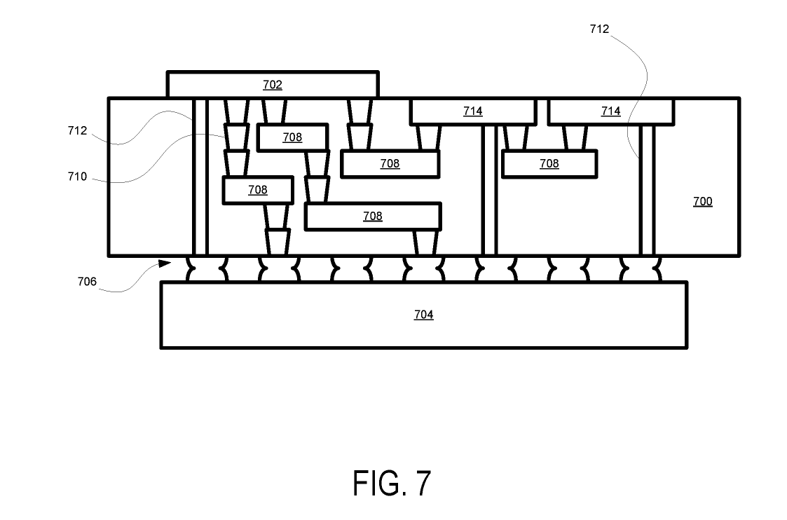

FIG. 7 illustrates an interposer, according to implementations. The interposer 700 may be an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. In one implementation, first substrate 702 may be an integrated circuit die described with respect to FIG. 2. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some implementations, the first and second substrates 702/704 are attached to opposing sides of the interposer 700. In other implementations, the first and second substrates 702/704 are attached to the same side of the interposer 700. In further implementations, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700.

In accordance with one or more implementations, apparatuses or processes disclosed herein may be used in the fabrication of interposer 700.

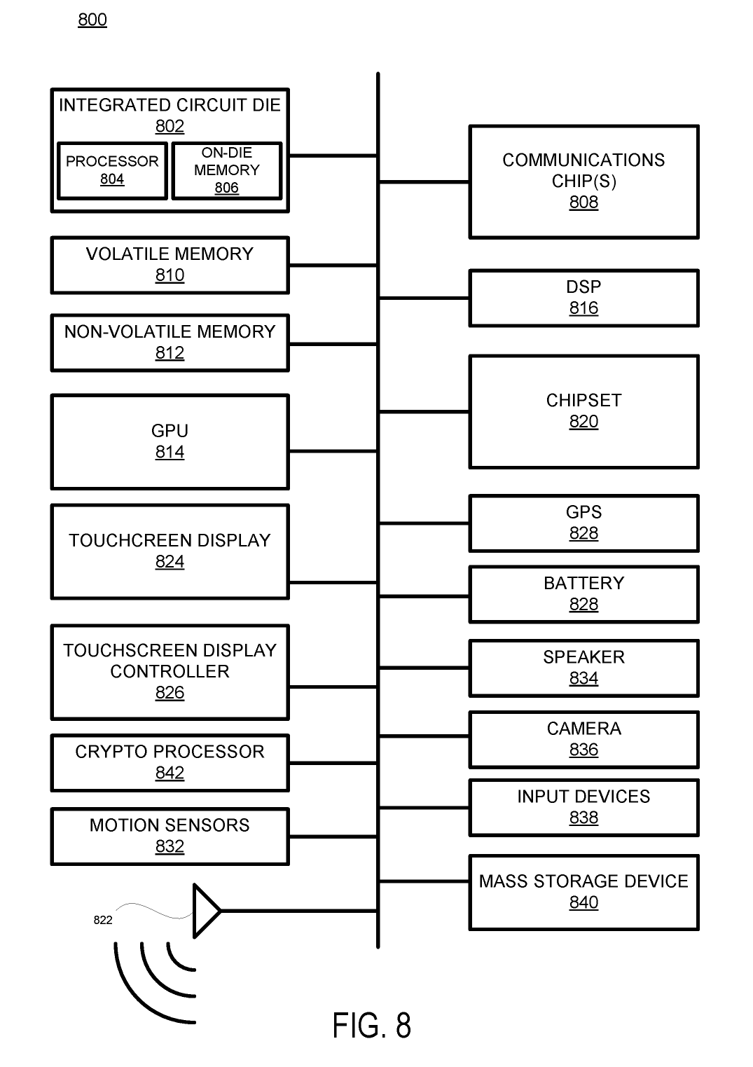

FIG. 8 is a computing device built in accordance implementation of the present disclosure. The computing device 800 may include a number of components. In one implementation, the components are attached to one or more motherboards. In an alternate implementation, some or all of these components are fabricated onto a single system-on-a-chip (SoC) die, such as an SoC used for mobile devices. The components in the computing device 800 include, but are not limited to, an integrated circuit die 802 and at least one communications logic unit 808. In some implementations the communications logic unit 808 is fabricated within the integrated circuit die 802 while in other implementations the communications logic unit 808 is fabricated in a separate integrated circuit chip that may be bonded to a substrate or motherboard that is shared with or electronically coupled to the integrated circuit die 802. The integrated circuit die 802 may include a CPU 804 as well as on-die memory 806, often used as cache memory, that can be provided by technologies such as embedded DRAM (eDRAM), SRAM, or spin-transfer torque memory (STT-MRAM). It should be appreciated that in implementations integrated circuit die 802 may include fewer elements (e.g., without processor 804 and/or on-die memory 806) or additional elements other than processor 804 and on-die memory 806. In one example, integrated circuit die 802 may be an LED with or without processor 804 and/or on-die memory 806. In another example, integrated circuit die 802 may be an HV circuit with or without processor 804 and/or on-die memory 806. In still another example, integrated circuit die 802 may be a circuit specific to RF applications that include a transceiver, RF amplifiers, RF filters, and/or other additional circuits (with or without processor 804 and/or on-die memory 806). In another example, integrated circuit die 802 may include some or all the elements described herein, as well as include additional elements.

Computing device 800 may include other components that may or may not be physically and electrically coupled to the motherboard or fabricated within an SoC die. These other components include, but are not limited to, volatile memory 810 (e.g., DRAM), non-volatile memory 812 (e.g., ROM or flash memory), a graphics processing unit 814 (GPU), a digital signal processor 816, a crypto processor 842 (e.g., a specialized processor that executes cryptographic algorithms within hardware), a chipset 820, at least one antenna 822 (in some implementations two or more antenna may be used), a display or a touchscreen display 824, a touchscreen controller 826, a battery 828 or other power source, a power amplifier (not shown), a voltage regulator (not shown), a global positioning system (GPS) device 828, a compass 830, a motion coprocessor or sensors 832 (that may include an accelerometer, a gyroscope, and a compass), a microphone (not shown), a speaker 834, a camera 836, user input devices 838 (such as a keyboard, mouse, stylus, and touchpad), and a mass storage device 840 (such as hard disk drive, compact disk (CD), digital versatile disk (DVD), and so forth). The computing device 800 may incorporate further transmission, telecommunication, or radio functionality not already described herein. In some implementations, the computing device 800 includes a radio that is used to communicate over a distance by modulating and radiating electromagnetic waves in air or space. In further implementations, the computing device 800 includes a transmitter and a receiver (or a transceiver) that is used to communicate over a distance by modulating and radiating electromagnetic waves in air or space.

The communications logic unit 808 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some implementations they might not. The communications logic unit 808 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 800 may include a plurality of communications logic units 808. For instance, a first communications logic unit 808 may be dedicated to shorter range wireless communications such as Wi-Fi, NFC, and Bluetooth and a second communications logic unit 808 may be dedicated to longer range wireless communications such as GPS, EDGE, GPRS, CDMA, WiMAX, LTE, Ev-DO, and others.

The processor 804 (also referred to processing device) of the computing device 800 includes one or more devices, such as transistors, RF filters, or LEDs, that are formed in accordance with implementations of the present disclosure. The term “processor” or “processing device” may refer to any device or portion of a device that processes electronic data from registers and/or memory to transform that electronic data into other electronic data that may be stored in registers and/or memory.

The communications logic unit 808 may also include one or more devices, such as transistors, RF filters, or LEDs, that are formed in accordance with implementations of the present disclosure.

In further implementations, another component housed within the computing device 800 may contain one or more devices, such as transistors, RF filters, or LEDs, that are formed in accordance with implementations of the present disclosure.

In various implementations, the computing device 800 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

Various operations are described as multiple discrete operations, in turn, in a manner that is most helpful in understanding the present disclosure, however, the order of description should not be construed to imply that these operations are necessarily order dependent. In particular, these operations need not be performed in the order of presentation.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present disclosure.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some implementations, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

In implementations, source and drain regions are formed within the substrate adjacent to the gate stack of each MOS transistor. The source and drain regions may be formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations, the epitaxially deposited silicon alloy may be doped in situ with dopants such as boron, arsenic, or phosphorous. In further implementations, the source and drain regions may be formed using one or more alternate semiconductor materials such as germanium or a group III-V material or alloy. In further implementations, one or more layers of metal and/or metal alloys may be used to form the source and drain regions.

In other implementations, one or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

What is claimed is:

1. A method of fabricating a wafer comprising:
forming a protective layer on a device side and a non-device side of a substrate of the wafer;
removing the protective layer from a center portion of the device side of the substrate while retaining the protective layer in an edge portion of the substrate; and
forming a semiconductor layer in the center portion of the device side of the substrate while the protective layer is in the edge portion of the substrate.

2. The method of fabricating the wafer of claim 1, wherein forming the semiconductor layer in the center portion of the device side of the substrate while the protective layer is in the edge portion of the substrate comprises:
growing the semiconductor layer in the center portion of the device side of the substrate and on at least part of the protective layer in the edge portion of the substrate, wherein the semiconductor layer in the center portion is crystalline and the semiconductor layer on the at least part of the protective layer in the edge portion is non-crystalline; and
etching the semiconductor layer to remove the non-crystalline semiconductor layer while retaining the crystalline semiconductor layer.

3. The method of fabricating the wafer of claim 1, wherein a mismatch of a coefficient of thermal expansion (CTE) between the semiconductor layer and the substrate is greater than 75 percent.

4. The method of fabricating the wafer of claim 1, wherein the semiconductor layer comprises a III-Nitride (III-N) material.

5. The method of fabricating the wafer of claim 1, wherein the semiconductor layer comprises Gallium Nitride (GaN).

6. The method of fabricating the wafer of claim 1, wherein the protective layer comprises at least one of silicon nitride or silicon dioxide.

7. The method of fabricating the wafer of claim 1, further comprising:
forming one or more additional semiconductor layers in the center portion of the device side of the substrate, wherein the one or more semiconductor layers comprise a III-Nitride (III-N).

8. The method of fabricating the wafer of claim 1, further comprising:
prior to forming the semiconductor layer, forming one or more transition layers in the center portion on the device side of the substrate.

9. The method of fabricating the wafer of claim 1, wherein the wafer has a diameter of 200 millimeters (mm) or larger.

10. A integrated circuit die comprising:
a substrate;
a protective layer disposed on a non-device side of the substrate; and
a semiconductor layer disposed on a device side of the substrate, wherein the semiconductor layer comprises a III-Nitride (III-N) material.

11. The integrated circuit die of claim 10, wherein the semiconductor layer comprises Gallium Nitride (GaN).

12. The integrated circuit die of claim 10, wherein a mismatch of a coefficient of thermal expansion (CTE) between the semiconductor layer and the substrate is greater than 75 percent.

13. The integrated circuit die of claim 10, further comprising:
one or more additional semiconductor layers disposed on the device side of the substrate, wherein the one or more additional semiconductor layers comprise the III-N material.

14. The integrated circuit die of claim 10, wherein the protective layer comprises at least one of silicon nitride or silicon dioxide.

15. A semiconductor wafer comprising:
a substrate having a device side and a non-device side;
a protective layer disposed on the substrate only on the non-device side of the substrate and within an edge portion; and
a semiconductor layer in a center portion on the device side of the substrate, wherein the semiconductor layer comprises a III-Nitride (III-N) material.

16. The semiconductor wafer of claim 15, wherein the semiconductor layer comprises Gallium Nitride (GaN).

17. The semiconductor wafer of claim 15, further comprising:
one or more additional semiconductor layers disposed on the device side of the substrate, wherein the one or more additional semiconductor layers comprise the III-N material.

18. The semiconductor wafer of claim 15, further comprising:
one or more transition layers interposed between the substrate and the semiconductor layer.

19. The semiconductor wafer of claim 15, wherein a mismatch of a coefficient of thermal expansion (CTE) between the semiconductor layer and the substrate is greater than 75 percent.

20. The semiconductor wafer of claim 15, wherein an area of the wafer adjacent to the edge portion has a Raman shift between 0 centimeters ⁻¹(cm⁻¹) and −1.4 (cm⁻¹).
